(19) United States
(12) Patent Application Publication
(10) Pub. No.: US 2022/0297259 A1
(43) Pub. Date: Sep. 22, 2022

(54) SYSTEM AND METHOD FOR EXCHANGING POLISH PLATE

(71) Applicant: Hermes Testing Solutions Inc., Hsinchu City (TW)

(72) Inventors: Tzu-Chien WANG, Hsinchu City (TW); Wen-Yuan HSU, Hsinchu City (TW)

(21) Appl. No.: 17/507,106

(22) Filed: Oct. 21, 2021

(30) Foreign Application Priority Data
Mar. 16, 2021 (TW) 110109380

(51) Int. Cl. B24B 53/00; B24B 37/12

(52) U.S. Cl. CPC B24B 53/00; B24B 37/12

(57) ABSTRACT

The present invention provides an automated system for exchanging polish plate, comprising a loading chamber to store polish plates ready for use, and the automated system has a mechanical arm to pick up and place polish plates between a test chamber and the loading chamber. The present invention realizes automated exchange of polish plates.

### BACKGROUND OF THE INVENTION

### 1. Field of the Invention

The present invention relates to a system and a method for exchanging polish plate, and particularly to an automated system and method for exchanging polish plate.

### 2. Description of the Prior Art

Generally, the electricity of a wafer should be tested after the wafer is manufactured. When an automatic or semi-automatic prober performs the probing, the surface or surroundings of the probes will be absorbed or stuck by the debris caused by contacting to the pads, bumps, or gold bumps of the wafer, and lead to data distortion. Therefore, it is necessary to use the cleaning material to remove the debris by polishing or sticking. The cleaning material must be attached to the polish plate and replaced regularly. When replacing, the prober must shut down and manually adjust the range and height of the cleaning material which causes a lower productivity and a higher probability of human error.

### SUMMARY OF THE INVENTION

The automated system for exchanging polish plate can achieve the purpose of automatic replacement by placing one or more backup polish plates at the preparing chamber in the prober and using the mechanical arm to take it out and move into the testing chamber. The present invention can save the time of shutting down the machine and personnel waste and increase productivity.

The present invention provides a system for exchanging a polish plate, comprising:
a testing chamber;
a loading chamber with a first buffer zone for storing a polish plate, wherein the loading chamber is connected to the testing chamber;
a base disposed in the testing chamber for carrying the polish plate; and
a first mechanical arm disposed in the testing chamber or the loading chamber for moving the polish plate.

The present invention provides a method for exchanging polish plates, comprising:
unloading a first polish plate from a base in a testing chamber to a first buffer zone in a loading chamber by a first mechanical arm; and
loading a second polish plate from the first buffer zone to the base by the first mechanical arm.

The present invention provides a method for loading polish plates, comprising:
adjusting a horizontal height of a base in a testing chamber; and
loading a first polish plate from the first buffer zone in a loading chamber to the base by the first mechanical arm.

### BRIEF DESCRIPTION OF THE DRAWINGS

FIG. 1 is a top view diagram of the system in a testing state.

FIG. 2 is a top view diagram of the system when loading the polish plate.

FIG. 3 is a top view diagram of the system when unloading the polish plate.

FIG. 4 is a top view diagram of another embodiment of the system when loading the polish plate.

FIGS. 5, 6 and 7 are side view diagrams of another embodiment of the system when loading/unloading the polish plate.

### DESCRIPTION OF THE PREFERRED EMBODIMENTS

Below embodiments accompanied with drawings are used to explain the spirit of this invention to have better understanding for the person in this art, not used to limit the scope of this invention, which is defined by the claims. The applicant emphasizes the element quantity and size are schematic only. Moreover, some parts might be omitted to skeletally represent this invention for conciseness.

The automated system for exchanging polish plate comprises a testing chamber and a loading chamber connected with the testing chamber, and the loading chamber is used for storing backup polish plates. By configuring a mechanical arm in the testing chamber or the loading chamber to pick up and place the polish plates for implementing automatic replacing system.

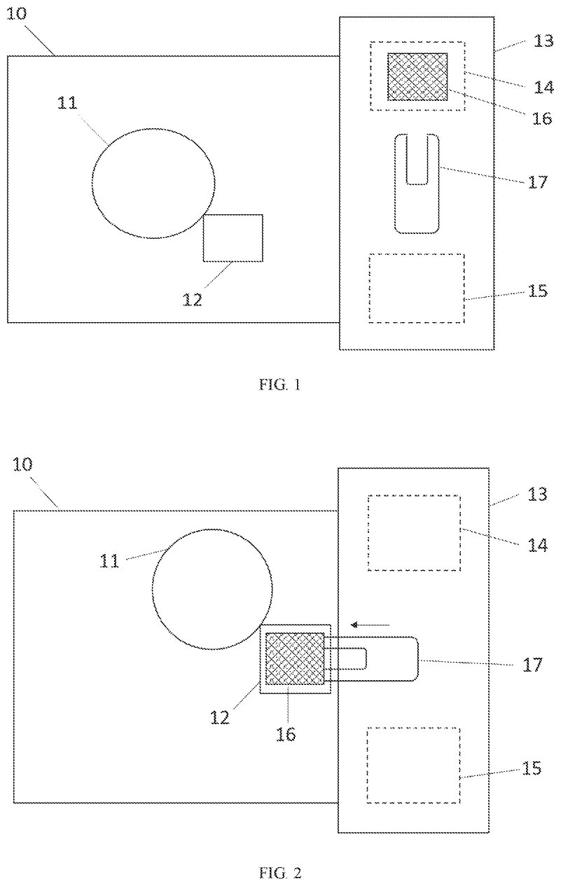

FIG. 1 is a top view diagram of the system for exchanging a polish plate in testing state. In an embodiment, the system comprises a testing chamber 10, a loading chamber 13, a base 12 and a first mechanical arm 17, wherein the loading chamber 13 is connected to the testing chamber 10. In an exchanging state, the testing chamber 10 and the loading chamber 13 are in communication, when in a cleaning state, the testing chamber 10 and the loading chamber 13 maintain communication or disconnection. A wafer chuck 11 and a base 12 are disposed in the testing chamber 10, wherein the base 12 is configured to carry a first polish plate 16 and can be optionally connected to the wafer chuck 11. A first mechanical arm 17 is configured in the testing chamber 10 or the loading chamber 13 for moving the first polish plate 16 or the wafer.

FIG. 2 is a top view diagram of the system when loading the polish plates. In this embodiment, the wafer chuck 11 and the base 12 move from a cleaning position to an exchanging position in the testing chamber 10, and the base 12 is adjusted to a predetermined horizontal height. Then, the first mechanical arm 17 picks up the first polish plate 16 at the first buffer zone 14 in the loading chamber 13 and loads it on the base 12. Lastly, the wafer chuck 11 and the base 12 move from the exchanging position to the cleaning position for probes cleaning. In cleaning state, the polish plate 16 can be moved from the base 12 to the wafer chuck 11, and then the probes can be cleaned by the polish plate 16 (not shown in FIG.).

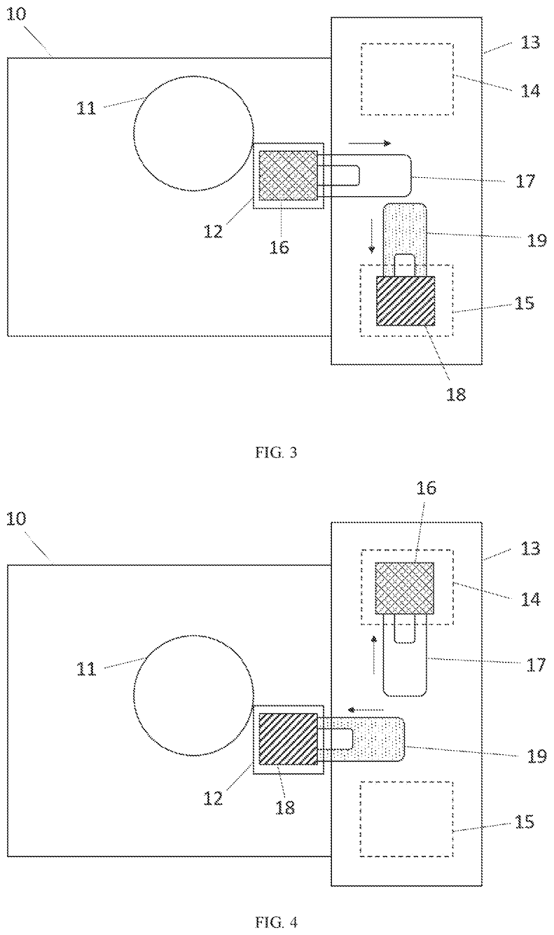

FIG. 3 and FIG. 4 are respectively top view diagrams of the system when unloading/loading the polish plates. In this embodiment, further comprising a second mechanical arm 19 and a second polish plate 18 which is disposed at the second buffer zone 15 in the loading chamber 13. First, the wafer chuck 11 and the base 12 move from the cleaning position to the exchanging position in the testing chamber 10, and the base 12 is adjusted to a predetermined horizontal height. Then, the first mechanical arm 17 unloads the first polish plate 16 on the base 12, and at the same time, the second mechanical arm 19 picks up the second polish plate 18 at the second buffer zone 15. Next, the first mechanical arm 17 moves the first polish plate 16 to the first buffer zone 14 in the loading chamber 13 and the second mechanical arm 19 loads the second polish plate 18 on the base 12 at the same time. Lastly, the wafer chuck 11 and the base 12 move from the exchanging position to the cleaning position for probes cleaning. In another embodiment, after the first mechanical arm 17 unloads the first polish plate 16, it can then pick up the second polish plate 18 at the second buffer zone 15 and loads it on the pedestal 12.

In other embodiments, the first buffer zone 14 and the second buffer zone 15 can simultaneously store a plurality of backup polish plates. Used polish plates can also be placed at the same buffer zone with the backup polish plates.

FIGS. 5, 6 and 7 are side view diagrams of the system when loading/unloading the polish plates. In this embodiment, further comprising a wafer chuck lifting unit 111 is disposed under the wafer chuck 11 (connect to the bottom of the wafer chuck) and a base lifting unit 121 is disposed under the base 12 (connect to the bottom of the base) for adjusting heights of the wafer chuck 11 and the base 12. The first mechanical arm 17 and the second mechanical arm 19 are arranged to extend in the same direction and can be extended simultaneously or independently to pick up or place the polish plates.

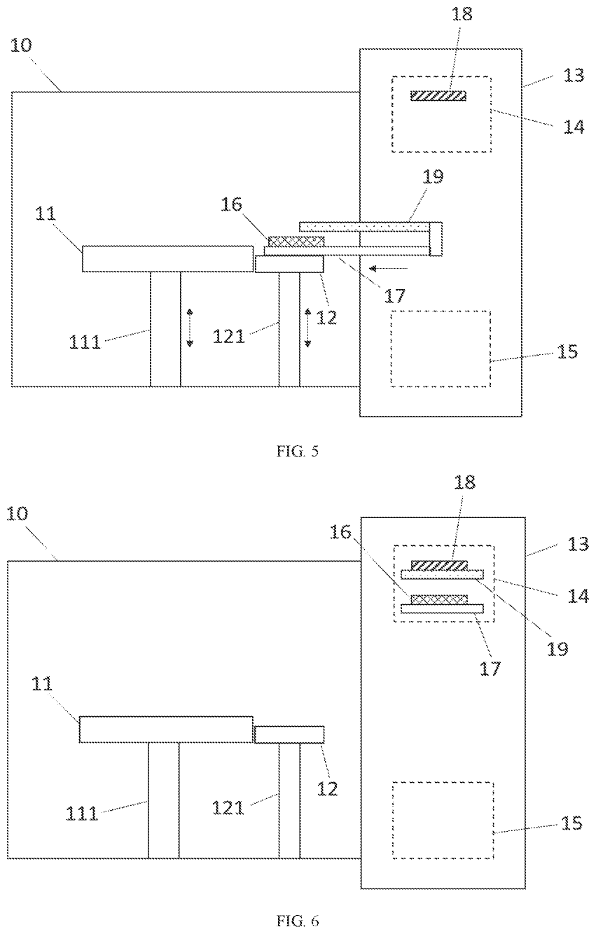

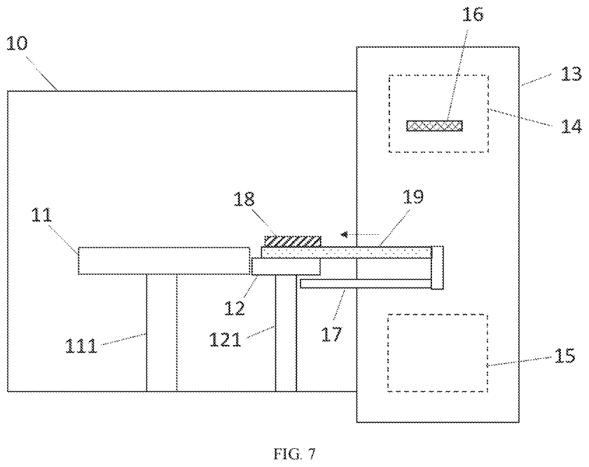

As shown in FIG. 5, first, the wafer chuck 11 and the base 12 move from the cleaning position to the exchanging position in the testing chamber 10, and the base 12 is adjusted to a predetermined horizontal height. Then, the first mechanical arm 17 extends to unload the first polish plate 16 on the base 12. As shown in FIG. 6, the first mechanical arm 17 and the second mechanical arm 19 turn to the first buffer zone 14 of the loading chamber 13 at the same time, the first mechanical arm 17 extends to move the first polish plate 16 to the first buffer zone 14, and the second mechanical arm 19 extends to pick up the second polish plate 18 at the first buffer zone 14. As shown in FIG. 7, the first mechanical arm 17 and the second mechanical arm 19 turn to the base 12 at the same time, the second mechanical arm 19 extends to load the second polish plate 18 on the pedestal 12. Lastly, the wafer chuck 11 and the base 12 move from the exchanging position to the cleaning position for probes cleaning.

In other embodiments, the system for exchanging polish plate further comprising a control unit (not shown in FIG.) controls the wafer chuck lifting unit 111 and the base lifting unit 121 for adjusting the height of the wafer chuck 11 and the base 12, and it controls the first mechanical arm 17 and the second mechanical arm 19 for operating the movement of the first mechanical arm 17 and the second mechanical arm 19.

In other embodiments, the base 12 comprises a vacuum unit (not shown in FIG.) for fixing the polish plate by vacuum suction, wherein the vacuum unit is controlled by the control unit.

By arranging the loading chamber to store the backup polish plates and using the mechanical arms for exchanging, the automated system and method for exchanging polish plate implement an automated apparatus and process for saving the time of shutting down the machine and personnel waste and increase productivity.

What is claimed is:

1. A system for exchanging a polish plate, comprising:
a testing chamber;
a loading chamber with a first buffer zone for storing a polish plate, wherein the loading chamber is connected to the testing chamber;
a base disposed in the testing chamber for carrying the polish plate; and
a first mechanical arm disposed in the testing chamber or the loading chamber for moving the polish plate.

2. The system according to claim 1, wherein the base is arranged at a cleaning position or an exchanging position in the testing chamber.

3. The system according to claim 1, wherein the loading chamber further comprising a second buffer zone for storing the polish plate.

4. The system according to claim 1, further comprising a second mechanical arm is disposed in the testing chamber or the loading chamber for moving the polish plate.

5. The system according to claim 1, wherein the base comprises a vacuum unit for fixing the polish plate by vacuum suction.

6. The system according to claim 1, further comprising:
a base lifting unit is connected to the bottom of the base; and
a control unit is connected to the base lifting unit and the first mechanical arm.

7. A method for exchanging polish plates, comprising:
unloading a first polish plate from a base in a testing chamber to a first buffer zone in a loading chamber by a first mechanical arm; and
loading a second polish plate from the first buffer zone to the base by the first mechanical arm.

8. The method according to claim 7, further comprising:
moving the base from a cleaning position in the testing chamber to an exchanging position in the testing chamber before unloading the first polish plate; and
moving the base from the exchanging position to the cleaning position after loading the second polish plate.

9. The method according to claim 7, further comprising adjusting a horizontal height of the base.

10. A method for loading polish plates, comprising:
adjusting a horizontal height of a base in a testing chamber; and
loading a first polish plate from the first buffer zone in a loading chamber to the base by the first mechanical arm.

11. The method according to claim 10, further comprising:
moving the base from a cleaning position in the testing chamber to an exchanging position in the testing chamber before loading the first polish plate; and
moving the base from the exchanging position to the cleaning position after loading the first polish plate.
